(19) United States
(12) Patent Application Publication
(10) Pub. No.: US 2009/0166082 A1
(43) Pub. Date: Jul. 2, 2009

(54) ANTI-ELECTROMAGNETIC-INTERFERENCE SIGNAL TRANSMISSION FLAT CABLE

(76) Inventors: Da-Yu Liu, Taipei City (TW); Da-Yung Liu, Taipei City (TW)

Correspondence Address: NIKOLAI & MERSEREAU, P.A., 900 SECOND AVENUE SOUTH, SUITE 820, MINNEAPOLIS, MN, 55402, US

(21) Appl. No.: 11/964,989

(22) Filed: Dec. 27, 2007

(51) Int. Cl. H01R 13/648; H01B 7/08; H05K 9/00; H01R 24/00

(52) U.S. Cl. 174/359; 174/117 F; 174/350

(57) ABSTRACT

An anti-electromagnetic-interference (anti-EMI) signal transmission flat cable include a plurality of conducting wires; and an insulating sheath being an integrally formed flat and flexible member for longitudinally enclosing a circumferential surface of each of the conducting wires, so that the conducting wires are substantially equally spaced and parallelly arranged in the insulating sheath to isolate from one another. The insulating sheath has an anti-EMI and electrically non-conductive material doped therein, so as to protect the conducting wires against EMI during signal transmission and accordingly, prevent errors in signal transmission via the conducting wires.

### FIELD OF THE INVENTION

The present invention relates to a signal transmission flat cable, and more particularly to a signal transmission flat cable including an integrally formed flat insulating sheath having an anti-EMI and electrically non-conductive material doped therein for enclosing conducting wires therein.

### BACKGROUND OF THE INVENTION

To enable convenient arrangement of multiple sets of signal transmission conductors in an electric or electronic device, conductors that have the same input and output are usually equally spaced and parallelly arranged. An IDE (Integrated Drive Electronics) cable is an example with such parallel conductor arrangement. Currently, the demands for data transmission between different devices are increased in geometrical series, and the working frequency of signal transmission lines quickly increases synchronously. For example, the rate of data transmission via the SATA (serial advanced technology attachment) cable has been increased from 150 Mb/s in the first generation SATA cable to 300 Mb/s and 600 MB/s in the second and the third generation SATA cable, respectively.

Due to the increasing data transmission rate, signals are more frequently switched and easily subject to electromagnetic interference (EMI) during the transmission thereof to cause errors in data being transmitted. In this case, the data must be transmitted again to result in largely lowered transmission efficiency. To overcome these problems, there are developed signal transmission cables with twisted conducting wires or metal-shielded conducting wires. Both the twisted cable and the metal-shielded cable have some disadvantages.

For example, the twisted cable has mutually twisted core wires to thereby have a relatively large size and occupy a relative large space. Since the size of the twisted cable multiplies when the number of core wires is increased, the twisted cable does not meet the requirement of manufacturing a compact and lightweight electric or electronic device.

On the other hand, the metal-shielded cable, such as a SATA signal transmission flat cable 1 shown in FIGS. 1, 2, and 3, includes a plurality of signal transmission conducting wires 10 that are individually and longitudinally enclosed in an inner insulating layer 12 to avoid electrical contact with one another. A metal layer 14 or a braided metal sheath is then provided around the inner insulating layer 12 to shield the signal transmission conducting wires 10 from external EMI and thereby prevent errors in data transmission. Finally, an outer insulating layer 16 is provided around the metal shielding layer 14 to isolate the metal layer 14 from external electricity.

While the metal-shielded cable occupies smaller space compared to the twisted cable, it includes multiple insulating and metal shielding layers and therefore requires longer process time and more labor and materials to increase the manufacturing cost thereof. As a matter of fact, the multiple insulating and metal shielding layers still inevitably increases the size of the metal-shielded cable.

Therefore, it is desirable to develop an improved signal transmission cable to overcome the problems in the conventional signal transmission cables.

### SUMMARY OF THE INVENTION

A primary object of the present invention is to provide an anti-electromagnetic-interference (anti-EMI) signal transmission flat cable to protect conducting wires thereof against EMI during signal transmission via the conducting wires.

Another object of the present invention is to provide an anti-EMI signal transmission flat cable that occupies reduced space and may be manufactured at reduced labor and material costs.

To achieve the above and other objects, the anti-EMI signal transmission flat cable according to the present invention includes a plurality of conducting wires and an insulating sheath. The insulating sheath is an integrally formed flat and flexible member for longitudinally enclosing a circumferential surface of each of the conducting wires, so that the conducting wires are substantially equally spaced and parallelly arranged in the insulating sheath to isolate from one another. The insulating sheath has an anti-EMI and electrically non-conductive material doped therein, so as to protect the conducting wires against electromagnetic interference during signal transmission and accordingly, prevent errors in signal transmission via the conducting wires.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of a conventional SATA signal transmission flat cable;

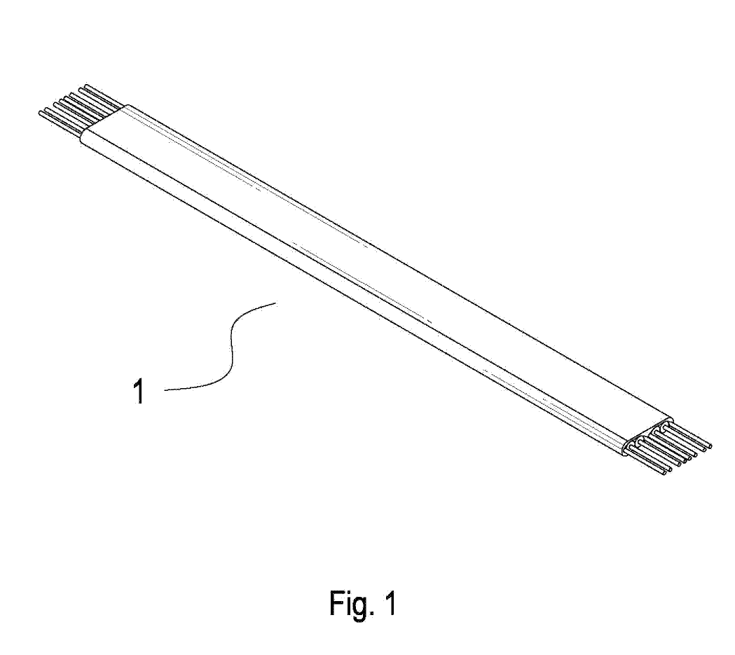

FIG. 2 is a fragmentary, enlarged, and partially sectioned perspective view of the conventional SATA signal transmission flat cable of FIG. 1;

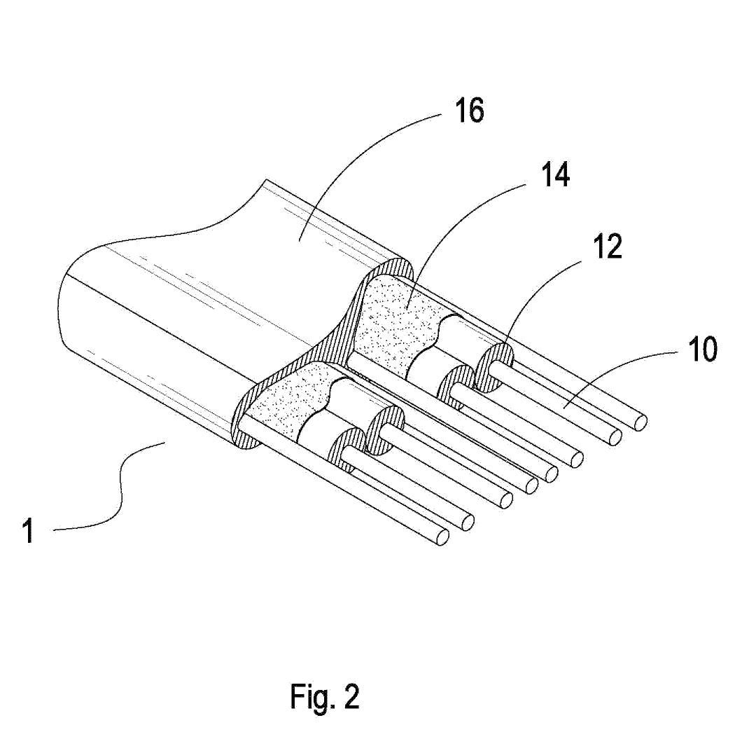

FIG. 3 is an enlarged cross sectional view of the conventional SATA signal transmission flat cable of FIGS. 1 and 2;

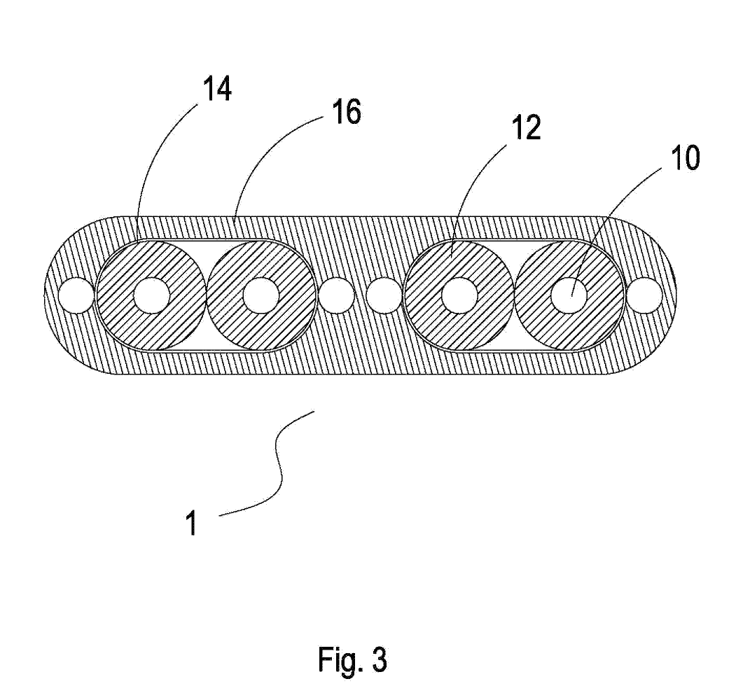

FIG. 4 is a perspective view of an anti-EMI signal transmission flat cable according to a first preferred embodiment of the present invention;

FIG. 5 is a fragmentary and enlarged perspective view of the anti-EMI signal transmission flat cable of FIG. 4;

FIG. 6 is an enlarged cross-sectional view of the anti-EMI signal transmission flat cable of FIGS. 4 and 5;

FIG. 7 is a fragmentary perspective view of an anti-EMI signal transmission flat cable according to a second preferred embodiment of the present invention; and

FIG. 8 is a fragmentary perspective view of an anti-EMI signal transmission flat cable according to a third preferred embodiment of the present invention.

### DETAILED DESCRIPTION OF THE PREFERRED EMBODIMENTS

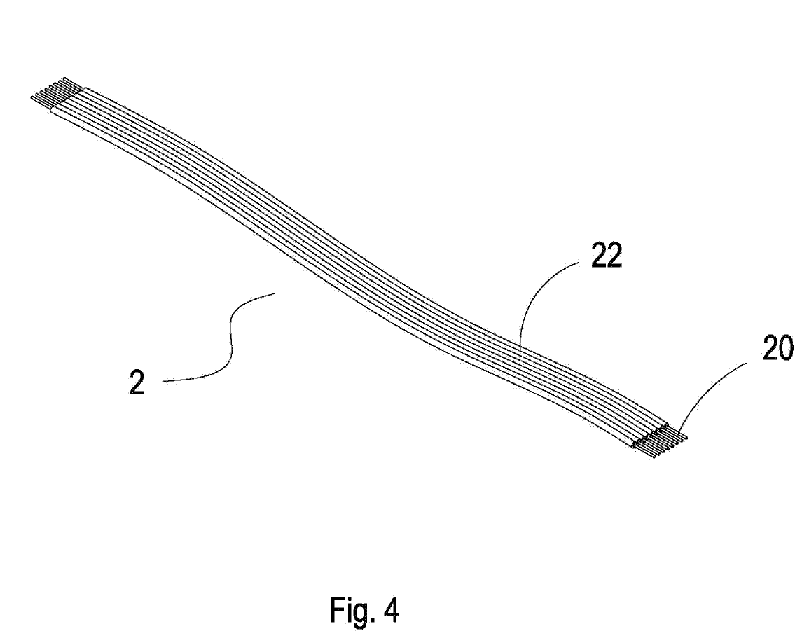

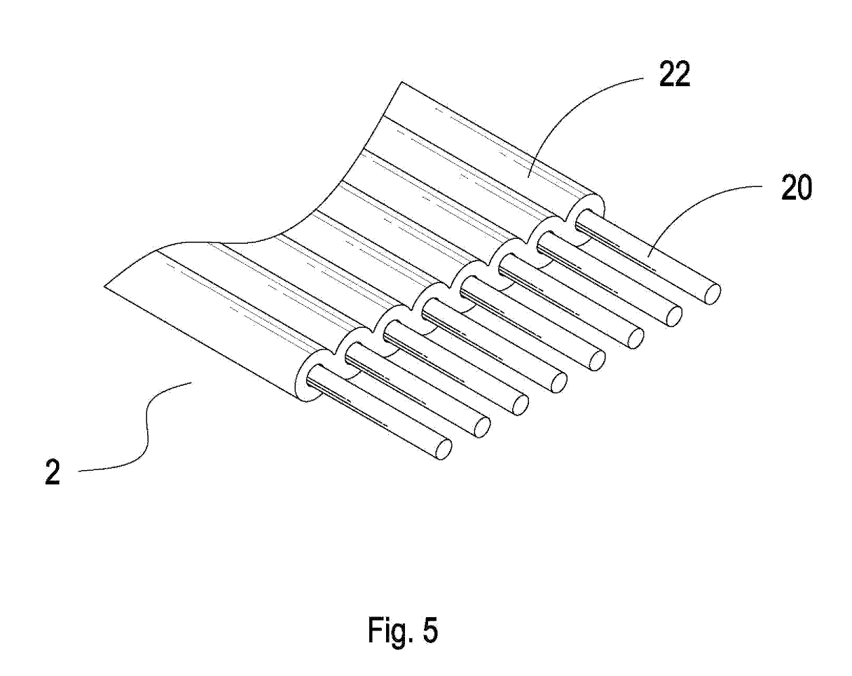

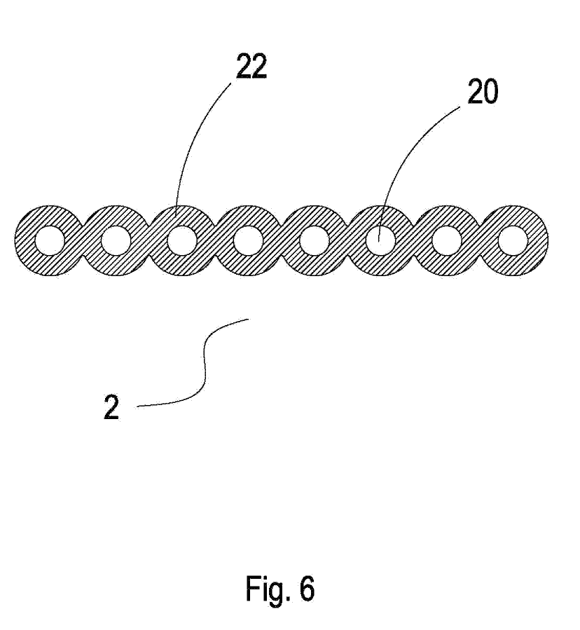

Please refer to FIGS. 4, 5, and 6, in which an anti-EMI signal transmission flat cable according to a first preferred embodiment of the present invention is shown. It is noted the illustrated signal transmission flat cable is a SATA flat cable having three earth lines and two sets of differential signal lines (that is, transmit (Tx) and receive (Rx) lines), based on which the present invention is described herein. However, the present invention may also be applied to signal transmission flat cables of other different specifications.

As shown, the anti-EMI signal transmission flat cable according to the present invention is generally denoted a reference number 2, and includes a plurality of conducting wires 20 and an insulating sheath 22.

The conducting wires 20 are normally copper wires, but may be selected from the group consisting of copper wires, silver wires, gold wires, and any combination thereof.

The insulating sheath 22 is an integrally formed flat and flexible member for longitudinally enclosing a circumferential surface of each of the conducting wires 20, so that the conducting wires 20 are substantially equally spaced and parallelly arranged in the insulating sheath 22 to isolate from one another. The insulating sheath 22 has an anti-EMI and electrically non-conductive material (not shown) doped therein, so as to protect the conducting wires 20 against electromagnetic interference during signal transmission and accordingly, prevent errors in signal transmission via the conducting wires 20. In the present invention, the anti-EMI and non-conductive material is an electrically non-conductive inorganic chemical compound.

The flat cable of the present invention is manufactured by integrally forming the insulating sheath 22 through injection molding, and then separately extending the conducting wires 20 through the insulating sheath 22. Alternatively, the conducting wires 20 are parallelly arranged before being enclosed in the insulating sheath 22.

The anti-EMI signal transmission flat cable of the present invention manufactured in the above described manners does not occupy a large space as would otherwise occur in the conventional signal transmission flat cable with twisted wires. Moreover, the signal transmission flat cable of the present invention does not include multiple insulating layers and metal shielding layer and therefore does not require lengthened process time and increased labor and materials. As a result, the signal transmission flat cable of the present invention is small in size and more suitable for use in the currently required compact electronic devices, and is cost-effective to enable largely increased competition ability in the market.

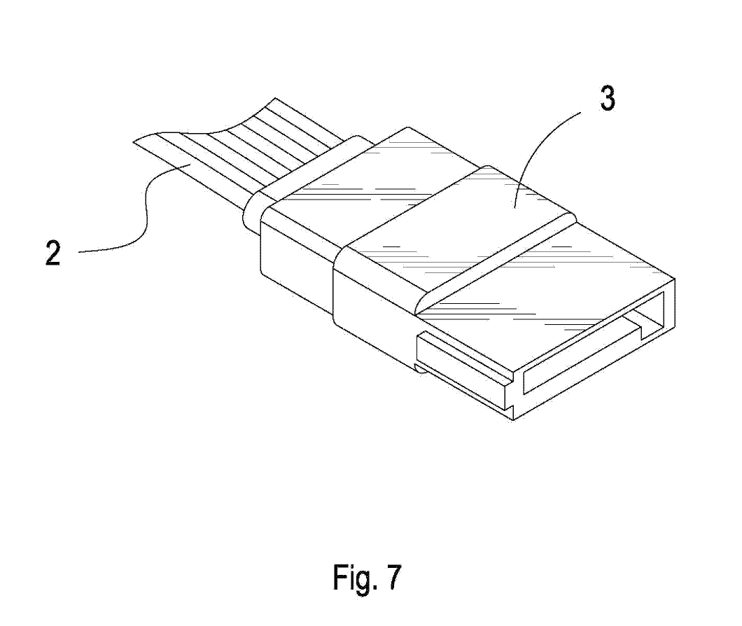

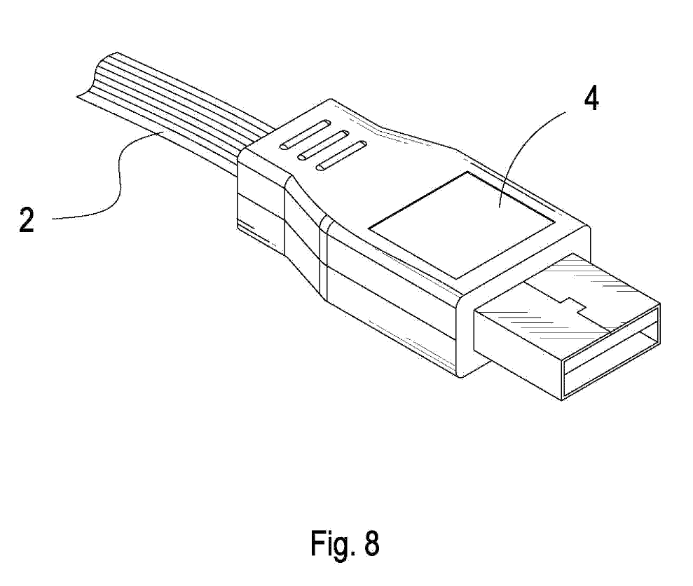

The anti-EMI signal transmission flat cable according to the present invention may have connectors connected to two ends thereof. FIGS. 7 and 8 are perspective views showing a second and a third preferred embodiment of the present invention, respectively. In the second embodiment, the flat cable 2 is provided at each end with a female connector 3 connected to the conducting wires 20, while in the third embodiment, the flat cable 2 is provided at each end with a male connector connected to the conducting wires 20. The connector 3 is internally provided with a plurality of terminals (not shown), to each of which one single conducting wire 20 is connected.

As having been mentioned above, the present invention may be applied to other signal transmission flat cables of different specifications, such as IDE (Integrated Drive Electronics), 1394, and USB (Universal Serial Bus) cables.

In brief, the signal transmission flat cable of the present invention includes an insulating sheath 22 having an anti-EMI and electrically non-conductive material doped therein, and can therefore effectively protect the conducting wires 20 against EMI and prevent errors in signal transmission caused by EMI. Besides, the insulating sheath 22 of the signal transmission flat cable of the present invention is integrally formed by injection molding to enclose individual conducting wires 20, enabling the flat cable to occupy minimized space and meet the requirement in manufacturing compact electronic device. Moreover, the anti-EMI signal transmission flat cable of the present invention may be manufactured with shortened process time, and reduced labor and material, and is therefore cost-effective to have largely increased competition ability in the market.

The present invention has been described with some preferred embodiments thereof and it is understood that many changes and modifications in the described embodiments can be carried out without departing from the scope and the spirit of the invention that is intended to be limited only by the appended claims.

What is claimed is:

1. An anti-electromagnetic-interference (anti-EMI) signal transmission flat cable, comprising:
a plurality of conducting wires; and
an insulating sheath being an integrally formed flat and flexible member for longitudinally enclosing a circumferential surface of each of the conducting wires, so that the conducting wires are substantially equally spaced and parallelly arranged in the insulating sheath to isolate from one another; and
wherein the insulating sheath has an anti-EMI and electrically non-conductive material doped therein, so as to protect the conducting wires against electromagnetic interference during signal transmission and accordingly, prevent errors in signal transmission via the conducting wires.

2. The anti-EMI signal transmission flat cable as claimed in claim 1, wherein the conducting wires are copper wires.

3. The anti-EMI signal transmission flat cable as claimed in claim 1, wherein the conducting wires are selected from the group consisting of copper wires, silver wires, gold wires, and any combination thereof.

4. The anti-EMI signal transmission flat cable as claimed in claim 1, wherein the conducting wires includes three earth wires and two sets of differential signal wires.

5. The anti-EMI signal transmission flat cable as claimed in claim 1, wherein the conducting wires are arranged according to SATA cable specification.

6. The anti-EMI signal transmission flat cable as claimed in claim 1, wherein the anti-EMI and electrically non-conductive material doped in the insulating sheath is an electrically non-conductive inorganic chemical compound.

7. The anti-EMI signal transmission flat cable as claimed in claim 1, further comprising a connector provided at each end thereof to connect to the conducting wires.

8. The anti-EMI signal transmission flat cable as claimed in claim 7, wherein the connectors are male connectors.

9. The anti-EMI signal transmission flat cable as claimed in claim 7, wherein the connectors are female connectors.

10. The anti-EMI signal transmission flat cable as claimed in claim 7, wherein the connectors are internally provided with a plurality of terminals, to each of which one single conducting wire is connected.
